(19) United States
(12) Patent Application Publication
(10) Pub. No.: US 2024/0224435 A1
(43) Pub. Date: Jul. 4, 2024

(54) METHOD FOR PRODUCING WIRING CIRCUIT BOARD

(71) Applicant: NITTO DENKO CORPORATION, Osaka (JP)

(72) Inventors: Hayato TAKAKURA, Osaka (JP); Naoki SHIBATA, Osaka (JP); Makoto TSUNEKAWA, Osaka (JP)

(73) Assignee: NITTO DENKO CORPORATION, Osaka (JP)

(21) Appl. No.: 18/550,252

(22) PCT Filed: Jan. 25, 2022
(86) PCT No.: PCT/JP2022/002678

§ 371 Date: Sep. 12, 2023

(30) Foreign Application Priority Data
Mar. 23, 2021 (JP) 2021-048253

(51) Int. Cl. H05K 3/46

(52) U.S. Cl. CPC H05K 3/4644

(57) ABSTRACT

A method for producing a wiring circuit board includes a step of forming an insulating layer on one surface in a thickness direction of a substrate, a step of forming a plurality of wirings on one surface in the thickness direction of the insulating layer, a step of forming an opening portion including the plurality of wirings when projected in the thickness direction in the substrate, a step of forming a resist pattern having an opening portion having a pattern shape along the plurality of wirings on the other surface in the thickness direction of the insulating layer, a step of forming a metal support portion by depositing a metal material on the insulating layer inside the opening portion, and a step of removing the resist pattern.

### TECHNICAL FIELD

The present invention relates to a method for producing a wiring circuit board.

### BACKGROUND ART

A wiring circuit board including a metal support substrate, an insulating layer on the metal support substrate, and a plurality of wirings on the insulating layer is known. In the wiring circuit board, in order to increase heat dissipation from the metal support substrate-side, for example, the metal support substrate is patterned so as to have a shape along the wiring, and the surface area of the metal support substrate is increased. A method for producing such a wiring circuit board is, for example, described in Patent Document 1 below.

### CITATION LIST

### Patent Document

Patent Document 1: Japanese Unexamined Patent Publication No. 2019-212659

### SUMMARY OF THE INVENTION

### Problem to be Solved by the Invention

In the method for producing a wiring circuit board described in Patent Document 1, the metal support substrate is patterned as follows. First, a resist pattern is formed on both sides in a thickness direction of the metal support substrate in which the insulating layer having a predetermined pattern and a wiring on the insulating layer are formed. The resist pattern masks a portion of the metal support substrate which is desired to be left. Next, an etching solution is sprayed against the substrate from one side or both sides in the thickness direction of the metal support substrate. The etching solution erodes the metal support substrate, and an eroded portion is removed (wet etching). By such a wet etching process, the metal support substrate is patterned, and a metal support portion along the wiring is formed for each wiring.

An opening portion of the resist pattern used for the wet etching process needs to be sufficiently wide so that a required amount of etching solution can pass.

Further, in the wet etching process, etching of the metal support substrate by the etching solution proceeds in the thickness direction of the substrate, and in addition, proceeds also in a plane direction perpendicular to the thickness direction even at a low speed. Therefore, there is a portion which is removed (formation of undercut) in the metal support substrate, even though masked by the resist pattern when projected in the thickness direction. A mask width of the resist pattern at a metal support portion to be formed-portion in the metal support substrate needs to be wider than the metal support portion to be formed-portion by an amount of length of the undercut.

In addition, the thicker the metal support substrate, the longer the time required for the wet etching process of the substrate, and therefore, the undercut to be formed is long. Therefore, it is required that the thicker the metal support substrate, the wider the resist pattern.

Design arrangement of the metal support portions which are adjacent to each other after patterning is determined by taking into account the size of the opening portion described above in the resist pattern and the length of the undercut. A distance between the adjacent metal support portions needs to be long enough to ensure the size of the opening portion and the length of the undercut. Such a method for producing a wiring circuit board is not appropriate for patterning the metal support substrate with fine pitch corresponding to the wiring formed with the fine pitch.

The present invention provides a method for producing a wiring circuit board appropriate for forming a metal support portion with fine pitch corresponding to a wiring formed with fine pitch.

### Means for Solving the Problem

The present invention [1] includes a method for producing a wiring circuit board including a first step of forming an insulating layer on one surface in a thickness direction of a substrate, a second step of forming a plurality of wirings on one surface in the thickness direction of the insulating layer, a third step of forming a first opening portion including the plurality of wirings when projected in the thickness direction in the substrate, a fourth step of forming a resist pattern having a second opening portion having a pattern shape along the plurality of wirings on the other surface in the thickness direction of the insulating layer, a fifth step of forming a metal support portion by depositing a metal material on the other surface in the thickness direction of the insulating layer inside the second opening portion, and a sixth step of removing the resist pattern.

In the method for producing a wiring circuit board of the present invention, as described above, in the third step, the first opening portion is formed in the substrate, and thereafter, through the fourth step and the fifth step, the metal support portion for supporting the wiring is formed. In the fifth step, by depositing the metal material into the second opening portion of the resist pattern, the metal support portion along the wiring is formed. Therefore, the arrangement of the metal support portions which are adjacent to each other depends on the arrangement of the second opening portion formed in the resist pattern. Since the resist pattern can be patterned by a photolithographic technique, it is easy to form the opening portions with fine pitch in the resist pattern. Further, in the production method, since the metal support portion is not formed by the wet etching process with respect to the metal support substrate, unlike the conventional production method described above, as for the arrangement of the metal support portion, it is not necessary to take into account the size of the opening portion of the resist pattern and the length of the undercut. Such a production method is appropriate for forming the metal support portion with the fine pitch corresponding to the wiring formed with the fine pitch.

The present invention [2] includes the method for producing a wiring circuit board described in the above-described [1] further including a seventh step of forming a third opening portion in the insulating layer between the wirings adjacent to each other after the sixth step.

Such a configuration is preferable to ensure the surface area of the insulating layer near the wiring and to enhance heat dissipation of the wiring.

The present invention [3] includes the method for producing a wiring circuit board described in the above-described [2], wherein the insulating layer has a thick portion and a thin portion; in the second step, the wiring is formed on the thick portion; and in the seventh step, the third opening portion is formed by removing the thin portion by an etching process from the other side in the thickness direction with respect to the insulating layer.

Such a configuration is preferable to appropriately form the above-described third opening portion in the insulating layer between the adjacent wirings.

The present invention [4] includes the method for producing a wiring circuit board described in any one of the above-described [1] to [3], wherein the metal support portion has a thickness of 20 μm or more and 300 μm or less.

Such a configuration is preferable to achieve both support strength and heat dissipation in the metal support portion.

### BRIEF DESCRIPTION OF THE DRAWINGS

FIG. 1 shows a plan view of a wiring circuit board produced by one embodiment of a method for producing a wiring circuit board of the present invention.

FIG. 2 shows a bottom view of the wiring circuit board shown in FIG. 1.

FIG. 3 shows a cross-sectional view along a III-III line of FIG. 1.

FIG. 4 shows a cross-sectional view along a IV-IV line of FIG. 1.

FIG. 5 shows a cross-sectional view along a V-V line of FIG. 1.

FIGS. 6A to 6C show a part of process views of one embodiment of a method for producing a wiring circuit board of the present invention:

FIG. 6A illustrating a base insulating layer forming step,

FIG. 6B illustrating a conductive layer forming step, and

FIG. 6C illustrating a cover insulating layer forming step.

FIGS. 7A to 7C show steps subsequent to the step shown in FIG. 6C:

FIG. 7A illustrating a first resist pattern forming step,

FIG. 7B illustrating a substrate patterning step, and

FIG. 7C illustrating a first resist pattern removing step.

FIGS. 8A to 8C show steps subsequent to the step shown in FIG. 7C:

FIG. 8A illustrating a second resist pattern forming step.

FIG. 8B illustrating a metal support layer forming step, and

FIG. 8C illustrating a second resist pattern removing step.

FIGS. 9A to 9C show steps subsequent to the step shown in FIG. 8C:

FIG. 9A illustrating a protective film forming step,

FIG. 9B illustrating a base insulating layer patterning step, and

FIG. 9C illustrating a protective film removing step.

### DESCRIPTION OF EMBODIMENTS

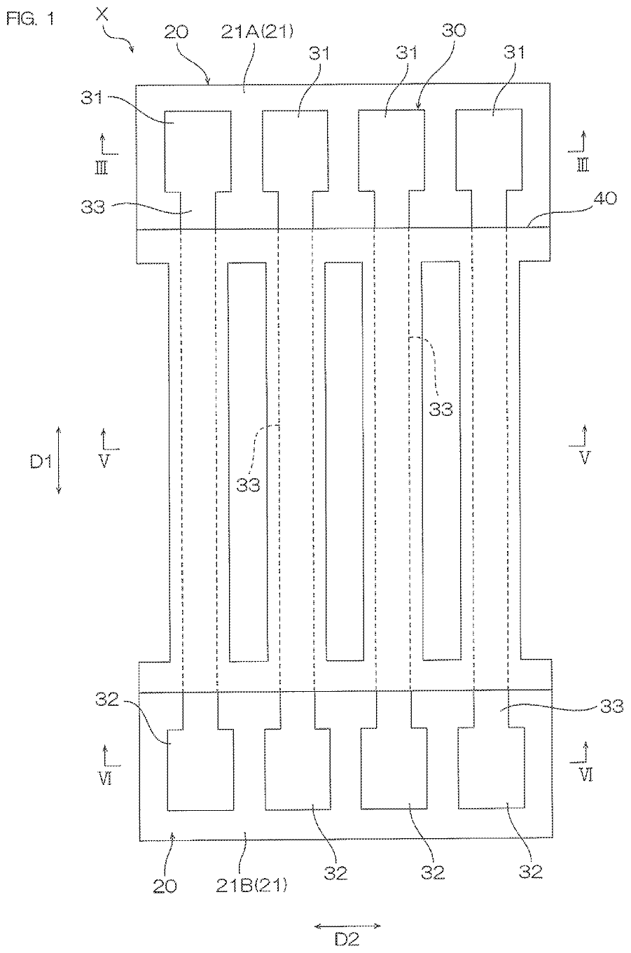

FIGS. 1 to 5 show a wiring circuit board X produced by one embodiment of a method for producing a wiring circuit board of the present invention. The wiring circuit board X includes a metal support layer 10, an insulating layer 20 as a base insulating laver, a conductive layer 30, and an insulating layer 40 as a cover insulating layer in order in a thickness direction T. The wiring circuit board X extends in a direction perpendicular to the thickness direction T (plane direction), and has a predetermined shape when viewed from the top. A shape when viewed from the top of the wiring circuit board X shown in FIGS. 1 and 2 is an illustrative shape.

The metal support layer 10 is a portion for ensuring strength of the wiring circuit board X. The metal support layer 10 includes a plurality of land portions 11 and a plurality of metal support portions 12, and has a predetermined pattern shape. A case where the metal support layer 10 includes the two land portions 11 and the four metal support portions 12 is illustratively shown.

The two land portions 11 (land portion 11A, land portion 11B) are separated in a first direction D1. The land portion 11A is disposed at one end in the first direction D1 in the wiring circuit board X. The land portion 11B is disposed at the other end in the first direction D1 in the wiring circuit board X. Each land portion 11 has a predetermined shape when viewed from the top. A case where the shape when viewed from the top of the land portion 11 is rectangular is illustratively shown. A thickness of the land portion 11 is preferably 20 μm or more, more preferably 50 μm or more, further more preferably 80 μm or more, and preferably 300 μm or less, more preferably 250 μm or less. The thickness of the land portion 11 may be the same as or different from the thickness of the metal support portion 12.

The plurality of metal support portions 12 are a portion for supporting a wiring 33 to be described later, and extend from the land portion 11A to the land portion 11B. A case where each metal support portion 12 linearly extends in the first direction D1 between the land portions 11A and 11B is illustratively shown. One end in the first direction D1 of the metal support portion 12 is connected to the land portion 11A. The other end in the first direction D1 of the metal support portion 12 is connected to the land portion 11B. A length (total length) from the land portion 11A to the land portion 11B in the metal support portion 12 is, for example, 5 to 40 mm.

The plurality of metal support portions 12 are spaced apart from each other in a second direction D2. The second direction D2 is perpendicular to the thickness direction T and the first direction D1. A width W1 of the metal support portion 12 (length in the second direction D2) is, for example, 10 μm or more, preferably 15 μm or more. The width W1 is, for example, 100 μm or less, preferably 50 μm or less. A separation distance d1 between the metal support portions 12 which are adjacent to each other is, for example, 50 μm or more, preferably 80 μm or more. The separation distance d1 is, for example, 300 μm or less, preferably 150 μm or less. A ratio (d1/W1) of the separation distance d1 to the width W1 of the metal support portion 12 is, for example, 0.5 or more, preferably 1.2 or more. The same ratio (d1/W1) is, for example, 30 or less, preferably 5 or less.

A thickness H1 of the metal support portion 12 is preferably 20 μm or more, more preferably 80 μm or more. The thickness H1 of the metal support portion 12 is preferably 300 μm or less, more preferably 250 μm or less. The ratio (H1/W1) of the thickness H1 to the width W1 of the metal support portion 12 is, for example, 0.2 or more, preferably 1.0 or more. The same ratio (H1/W1) is, for example, 30 or less, preferably 5 or less. These configurations are preferable to achieve both support strength and heat dissipation in the metal support portion 12. Further, the ratio (H1/H2) of the thickness H1 of the metal support portion 12 to a thickness H2 of the wiring 33 to be described later is, for example, 0.4 or more, preferably 3.0 or more. The same ratio (H1/H2) is, for example, 100 or less, preferably 25 or less.

Examples of a material for the metal support layer 10 include copper, copper alloys, aluminum, nickel, titanium, and 42-alloys. From the viewpoint of the strength of the metal support layer 10, the metal support layer 10 preferably includes at least one kind selected from the group consisting of copper, copper alloys, aluminum, nickel, and titanium, and more preferably is made of at least one kind selected from the group consisting of copper, copper alloys, aluminum, nickel, and titanium. From the viewpoint of achieving both the strength and flexibility of the metal support layer 10, the metal support layer 10 is preferably made of copper or a copper alloy.

The insulating layer 20 is disposed at one side in the thickness direction T in the metal support layer 10. In the present embodiment, the insulating layer 20 is disposed on one surface in the thickness direction T in the metal support layer 10. The insulating layer 20 includes a plurality of first portions 21 and a plurality of second portions 22, and has a predetermined pattern shape. A case where the insulating layer 20 includes the two first portions 21 (first portion 21A, first portion 21B) and the four second portions 22 is illustratively shown.

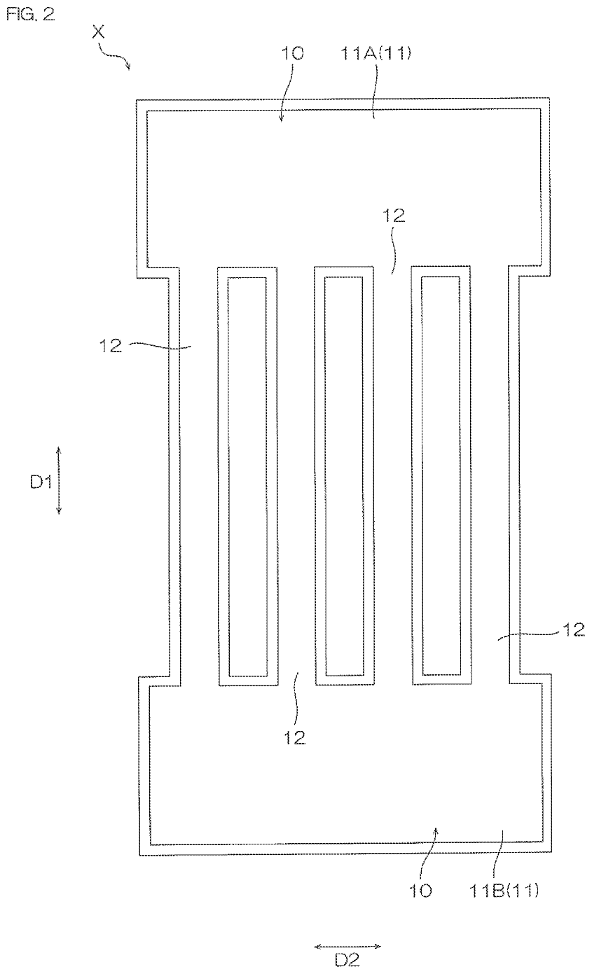

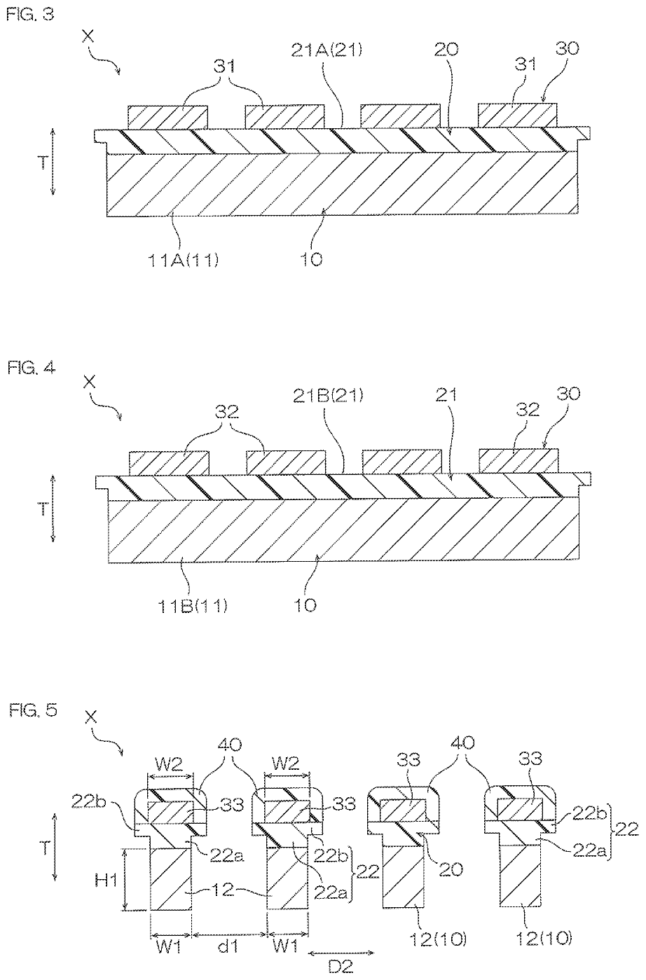

As shown in FIGS. 1 and 3, the first portion 21A is disposed on the land portion 11A of the metal support layer 10. As shown in FIGS. 1 and 4, the first portion 21B is disposed on the land portion 11B. Each first portion 21 has a predetermined shape when viewed from the top. A case where the shape when viewed from the top of the first portion 21 is rectangular is illustratively shown. The thickness of the first portion 21 is preferably 1 μm or more, more preferably 3 μm or more, and preferably 35 μm or less, more preferably 20 μm or less.

The second portion 22 is disposed along the metal support portion 12 for each metal support portion 12, and extends from the first portion 21A to the first portion 21B. The plurality of portions 22 are disposed corresponding to the plurality of metal support portions 12 to be apart from each other in the second direction D2. One end in the first direction D1 of each second portion 22 is connected to the first portion 21A. The other end in the first direction D1 of each second portion 22 is connected to the first portion 21B.

As shown in FIG. 5, the second portion 22 has a thick portion 22a and a thin portion 22b which is thinner than the thick portion 22a. The thick portion 22a is disposed on the metal support portion 12. The thin portion 22b is disposed on each of both sides in the second direction D2 of the thick portion 22a. A thickness H3 of the thick portion 22a is preferably 1 μm or more, more preferably 3 μm or more, and preferably 35 μm or less, more preferably 20 μm or less. A thickness H4 of the thin portion 22b is preferably 0.5 μm or more, more preferably 1 μm or more, and preferably below 35 μm, more preferably 20 μm or less as long as it is thinner than the thick portion 22a. The ratio (H4/H3) of the thickness H4 to the thickness H3 is preferably 0.1 or more, more preferably 0.2 or more, and preferably below 1, more preferably 0.9 or less.

Examples of the material for the insulating layer 20 include resin materials such as polyimide, polyether nitrile, polyether sulfone, polyethylene terephthalate, polyethylene naphthalate, and polyvinyl chloride, and preferably, polyimide is used (the same applies to the material for the insulating layer 40 to be described later).

The conductive layer 30 is disposed at one side in the thickness direction T in the insulating layer 20. In the present embodiment, the conductive layer 30 is disposed on one surface in the thickness direction T in the insulating layer 20. The conductive layer 30 includes a plurality of first terminal portions 31, a plurality of second terminal portions 32, and the plurality of wirings 33, and has a predetermined pattern shape.

The first terminal portion 31 is disposed on the first portion 21A. The plurality of first terminal portions 31 are spaced apart from each other in the second direction D2. The second terminal portion 32 is disposed on the first portion 21B. The plurality of second terminal portions 32 are spaced apart from each other in the second direction D2. The shape when viewed from the top of the first terminal portion 31 and the shape when viewed from the top of the second terminal portion 32 are wider than the wiring 33 in the second direction D2. Examples of the shape when viewed from the top of the terminal portions 31 and 32 include circles, quadrangles, and rounded quadrangles. Examples of the quadrangle include squares and rectangles. Examples of the rounded quadrangle include rounded squares and rounded rectangles. A case where the shape when viewed from the top of the terminal portions 31 and 32 is rectangular is illustratively shown.

The wiring 33 is disposed on the first portion 21A, on the second portion 22, and on the first portion 21B in the insulating layer 20, and extends in the first direction D1. The plurality of wirings 33 are disposed corresponding to the plurality of second portions 22 to be apart from each other in the second direction D2. One end in the first direction D1 of each wiring 33 is connected to the first terminal portion 31. The other end in the first direction D1 of each wiring 33 is connected to the second terminal portion 32.

A width W2 (length in the second direction D2) of the wiring 33 is, for example, 10 μm or more, preferably 20 μm or more. The width W2 is, for example, 80 μm or less, preferably 50 μm or less. The ratio (W2/W1) of the width W2 of the wiring 33 to the width W1 of the metal support portion 12 described above is, for example, 0.1 or more, preferably 0.3 or more. The same ratio (W2/W1) is, for example, 4 or less, preferably 2 or less.

A separation distance d2 between the wirings 33 which are adjacent to each other is, for example, 50 μm or more, preferably 80 μm or more. The separation distance d2 is, for example, 300 μm or less, preferably 150 μm or less. The ratio (d2/W2) of the separation distance d2 to the width W2 of the wiring 33 is, for example, 0.6 or more, preferably 1 or more. The same ratio (d2/W2) is, for example, 30 or less, preferably 7.5 or less.

Examples of a material for the conductive layer 30 include copper, nickel, gold, and alloys of these, and preferably, copper is used. The thickness of the conductive layer 30 is, for example, 3 μm or more, preferably 5 μm or more. The thickness of the conductive layer 30 is, for example, 50 μm or less, preferably 30 μm or less.

The insulating layer 40 is disposed at one side in the thickness direction T of the insulating layer 20 so as to cover the conductive layer 30. In the present embodiment, the insulating layer 40 is disposed on one surface in the thickness direction T of the insulating layer 20 so as to cover the wiring 33. The thickness of the insulating layer 40 on the insulating layer 20 and the wiring 33 is preferably 2 μm or more, more preferably 4 μm or more, and preferably 60 μm or less, more preferably 40 μm or less.

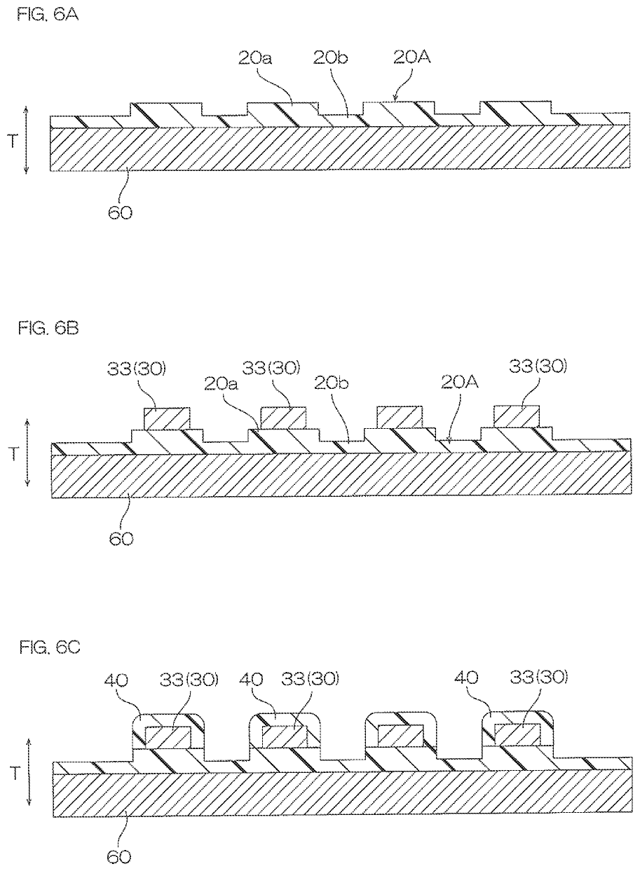

FIGS. 6A to 9C show one embodiment of a method for producing a wiring circuit board of the present invention. FIGS. 6A to 9C show the production method as a change in a cross section corresponding to FIG. 5. In the present embodiment, the production method includes a base insulating layer forming step, a conductive layer forming step, a cover insulating layer forming step, a first resist pattern forming step, a substrate patterning step, a first resist pattern removing step, a second resist pattern forming step, a metal support layer forming step, a second resist pattern removing step, a protective film forming step, a base insulating layer patterning step, and a protective film removing step.

In the production method, first, as shown in FIG. 6A, an insulating layer 20A is formed on one surface in the thickness direction T of a substrate 60 (base insulating layer forming step).

The substrate 60 is preferably made of a metal substrate. Examples of the material for the metal substrate include stainless steel, copper, copper alloys, nickel, titanium, and 42-alloys. An example of the stainless steel includes SUS304 based on standards of AISI (American Iron and Steel Institute). The thickness of the substrate 60 is, for example, 10 to 50 μm.

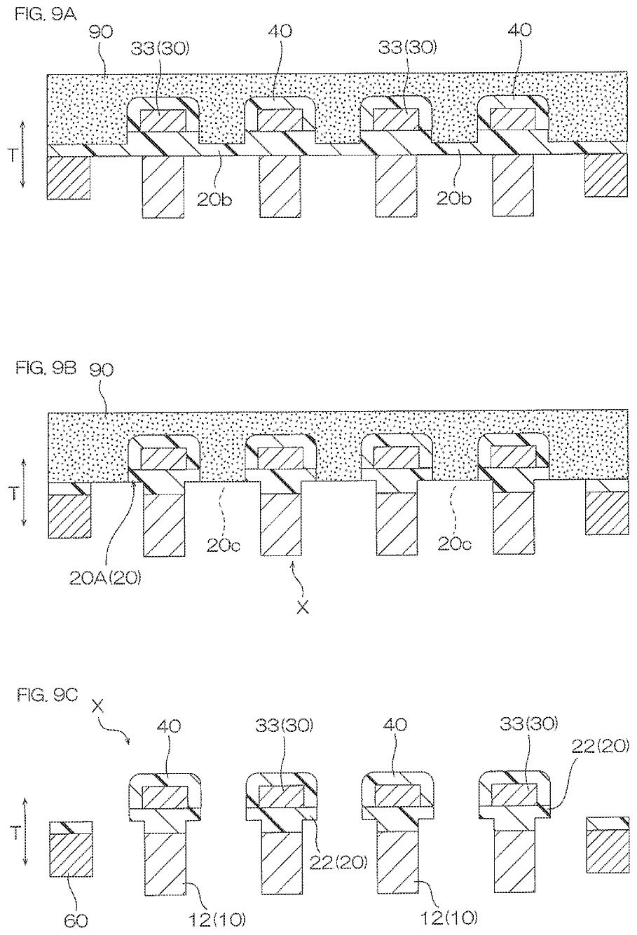

The insulating layer 20A includes a relatively thick first region 20a (thick portion) and a relatively thin second region 20b (thin portion). The first region 20a is a portion to serve as the insulating layer 20 by remaining in the patterning step (shown in FIG. 9B) to be described later of the insulating layer 20A.

In this step, for example, the insulating layer 20A is formed as follows. First, a solution (varnish) of a positive photosensitive resin is coated onto the substrate 60, thereby forming a coating film. Next, the coating film is dried by heating. Next, the coating film is subjected to an exposure process through a predetermined mask, a subsequent development process, and thereafter, a bake process as needed. In the exposure process, an exposure amount with respect to a first region 20a to be formed-portion is relatively reduced, and the exposure amount with respect to a second region 20b to be formed-portion is relatively increased. Thus, the insulating layer 20A including the first region 20a and the second region 20b can be formed in this step. This step corresponds to the first step of the present invention.

Next, as shown in FIG. 6B, the above-described conductive layer 30 is formed on the first region 20a of the insulating layer 20A (conductive layer forming step). In this step, first, a first seed layer (not shown) is formed on the insulating layer 20A by, for example, a sputtering method. Examples of the material for the seed layer include Cr, Cu. Ni, Ti, and alloys of these. The seed layer may have a single layer structure or a two layer or more multilayer structure. When the seed layer has the multilayer structure, the seed layer consists of, for example, a chromium layer as a lower layer and a copper layer on the chromium layer. Next, a resist pattern is formed on the seed layer. The resist pattern has an opening portion having a shape corresponding to a pattern shape of the conductive layer 30. In forming the resist pattern, for example, a photosensitive resist film is attached onto a seed layer, thereby forming a resist film. Thereafter, the resist film is subjected to the exposure process through the predetermined mask, the subsequent development process, and thereafter, the bake process as needed. In forming the conductive layer 30, next, as for the conductive layer 30, the above-described metal is grown on the seed layer inside the opening portion of the resist pattern by an electrolytic plating method. Next, the resist pattern is removed by etching. Next, a portion exposed by the resist pattern removal in the seed layer is removed by the etching. For example, as described above, the conductive layer 30 having a predetermined pattern (the first terminal portion 31, the second terminal portion 32, the wiring 33) is formed on the first region 20a. This step corresponds to the second step of the present invention.

Next, as shown in FIG. 6C, the insulating layer 40 is formed on the insulating layer 20A so as to cover the conductive layer 30 (cover insulating layer forming step). In this step, first, a solution (varnish) of a photosensitive resin is coated onto the insulating layer 20A and the conductive layer 30, thereby forming a coating film. Next, the coating film is dried. Next, the coating film is subjected to the exposure process through the predetermined mask, the subsequent development process, and thereafter, the bake process as needed. For example, as described above, it is possible to form the insulating layer 40 having a predetermined pattern.

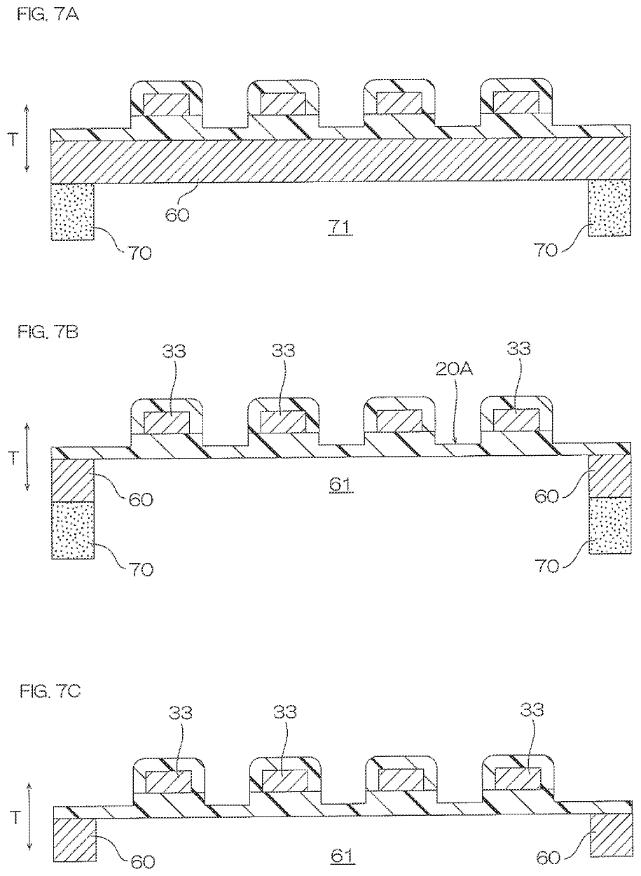

Next, as shown in FIG. 7A, a resist pattern 70 is formed on the other surface in the thickness direction T of the substrate 60 (first resist pattern forming step). The resist pattern 70 has an opening portion 71, and has a frame shape for masking a peripheral portion of the substrate 60 when viewed from the top. The opening portion 71 has a shape including the above-described wiring circuit board X when projected in the thickness direction. In forming the resist pattern 70, for example, a photosensitive resist film is attached onto the other surface in the thickness direction T of the substrate 60, thereby forming a resist film. Thereafter, the resist film is subjected to the exposure process through the predetermined mask, the subsequent development process, and thereafter, the bake process as needed (the same applies to a method for forming a resist pattern 80 to be described below).

Next, as shown in FIG. 7B, an opening portion 61 (first opening portion) is formed in the substrate 60 (substrate patterning step). In this step, the substrate 60 is subjected to a wet etching process from the other side in the thickness direction T with the resist pattern 70 as an etching mask. Examples of an etching solution for the wet etching include ferric chloride aqueous solutions and cupric chloride solutions. The concentration of the etching solution is, for example, 30 to 55% by mass. A temperature of the etching solution is, for example, 20° C. to 55° C. The etching time is, for example, 1 to 15 minutes. The opening portion 61 thus formed has a shape including the above-described wiring circuit board X when projected in the thickness direction. That is, the opening portion 61 has a shape including the above-described plurality of wirings 33 when projected in the thickness direction. This step corresponds to the third step of the present invention. Further, after this step, in the present embodiment, a second seed layer (not shown) is formed on the other surface in the thickness direction T of the insulating layer 20A by, for example, the sputtering method. The material and a layer configuration of the second seed layer are the same as those of the above-described first seed layer with reference to FIG. 6B.

Next, as shown in FIG. 7C, the resist pattern 70 is removed (first resist pattern removing step).

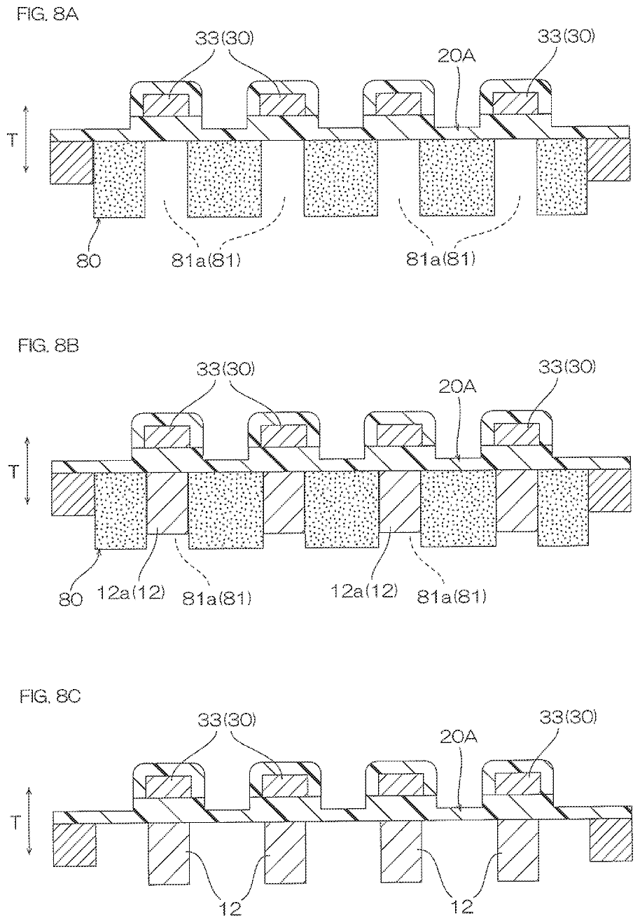

Next, as shown in FIG. 8A, the resist pattern 80 is formed on the other surface in the thickness direction T of the insulating layer 20A (second resist pattern forming step). The resist pattern 80 has an opening portion 81. The opening portion 81 has a pattern shape corresponding to the above-described conductive layer 30 when viewed from the top. The opening portion 81 includes an opening portion 81a (second opening portion) having a pattern shape along the plurality of wirings 33 when projected in the thickness direction. This step corresponds to the fourth step of the present invention.

Next, as shown in FIG. 8B, a metal material 12a is deposited on the other surface in the thickness direction T of the insulating layer 20A inside the opening portion 81, thereby forming the above-described metal support layer 10 (metal support layer forming step). In this step, specifically, the metal material 12a is grown on the seed layer (second seed layer) inside the opening portion 81 of the resist pattern 80 by the electrolytic plating method. Thus, the metal support layer 10 is formed inside the opening portion 81. In the opening portion 81, the metal support portion 12 is formed by depositing the metal material 12a. This step corresponds to the fifth step of the present invention.

Next, as shown in FIG. 8C, the resist pattern 80 is removed (second resist pattern removing step). This step corresponds to the sixth step of the present invention. After removing the resist pattern 80, a portion exposed by the resist pattern removal in the second seed layer is removed by the etching.

Next, as shown in FIG. 9A, a protective film 90 covering the conductive layer 30 and the cover insulating layer 40 is formed at one side in the thickness direction T of the insulating layer 20A (protective film forming step). As the protective film 90, for example, a dry film resist can be used.

Next, as shown in FIG. 9B, the insulating layer 20A is patterned (base insulating layer patterning step). In this step, an opening portion 20c (third opening portion) is formed by removing the second region 20b of the insulating layer 20A by the wet etching process from the other side in the thickness direction T with respect to the insulating layer 20A. Thus, the above-described insulating layer 20 is formed, so that the wiring circuit board X held by a frame-shaped substrate 70 through the protective film 90 is obtained. This step corresponds to the seventh step of the present invention.

Next, as shown in FIG. 9C, the protective film 90 is removed (protective film removing step). By removing the protective film 90, the wiring circuit board X is isolated. As described above, the wiring circuit board X is produced.

In the above-described method for producing a wiring circuit board, in the conductive layer forming step (FIG. 8B), by depositing the metal material 12a into the opening portion 81a of the resist pattern 80, the metal support portion 12 along the wiring 33 is formed. Therefore, the arrangement of the adjacent metal support portions 12 depends on the arrangement of the opening portion 81a formed in the resist pattern 80. Since the resist pattern can be patterned by a photolithographic technique, it is easy to form the opening portions with fine pitch in such a resist pattern. Further, in the production method, since the metal support portion 12 is not formed by the wet etching process with respect to the metal support substrate, as for the arrangement of the metal support portion 12, it is not necessary to take into account the size of the opening portion of the resist pattern and the length of the undercut. Such a production method is appropriate for forming the metal support portion with the fine pitch corresponding to the wiring formed with the fine pitch. The width W1 of the metal support portion 12, the separation distance d1 between the adjacent metal support portions 12, the ratio (d1/W1) of the separation distance d1 to the width W1, and the ratio (H1/W1) of the thickness H1 of the metal support portion 12 to the width W1 are as described above.

As described above, the production method includes the base insulating layer patterning step (FIG. 9B) of forming the opening portion 20c in the insulating layer 20A between the adjacent wirings 33. Such a configuration is preferable to ensure the surface area of the insulating layer 20 near the wiring 33 and to enhance heat dissipation of the wiring 33.

In the production method, the insulating layer 20A formed in the base insulating layer forming step (FIG. 6A) has the first region 20a (thick portion) and the second region 20b (thin portion); in the conductive layer forming step (FIG. 6B), the wiring 33 is formed on the first region 20a; and in the base insulating layer patterning step (FIG. 9B), by the etching process from the other side in the thickness direction with respect to the insulating layer 20A, the second region 20b (thin portion) is removed, thereby forming the opening portion 20c. Such a configuration is preferable to appropriately form the opening portion 20c in the insulating layer 20A between the adjacent wirings 33.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICATION

The method for producing a wiring circuit board of the present invention can be applied to a method for producing a wiring circuit board including a support portion which supports a wiring.

### DESCRIPTION OF REFERENCE NUMERALS

X Wiring circuit board
D1 First direction
D2 Second direction
T Thickness direction
10 Metal support layer
11 Land portion
12 Metal support portion
12a Metal material
20, 40 Insulating layer
20A Insulating layer
20a First region (thick portion)
20b Second region (thin portion)
21 First portion
22 Second portion
22a Thick portion
22b Thin portion
30 Conductive layer
33 Wiring
60 Substrate
61 Opening portion (first opening portion)
80 Resist pattern
81 Opening portion (second opening portion)

1. A method for producing a wiring circuit board comprising:
a first step of forming an insulating layer on one surface in a thickness direction of a substrate,
a second step of forming a plurality of wirings on one surface in the thickness direction of the insulating layer,
a third step of forming a first opening portion including the plurality of wirings when projected in the thickness direction in the substrate,
a fourth step of forming a resist pattern having a second opening portion having a pattern shape along the plurality of wirings on the other surface in the thickness direction of the insulating layer,
a fifth step of forming a metal support portion by depositing a metal material on the other surface in the thickness direction of the insulating layer inside the second opening portion, and
a sixth step of removing the resist pattern.

2. The method for producing a wiring circuit board according to claim 1 further comprising:
a seventh step of forming a third opening portion in the insulating layer between the wirings adjacent to each other after the sixth step.

3. The method for producing a wiring circuit board according to claim 2, wherein
the insulating layer has a thick portion and a thin portion; in the second step, the wiring is formed on the thick portion; and in the seventh step, the third opening portion is formed by removing the thin portion by an etching process from the other side in the thickness direction with respect to the insulating layer.

4. The method for producing a wiring circuit board according to claim 1, wherein
the metal support portion has a thickness of 20 μm or more and 300 μm or less.
